(19) United States
(12) Patent Application Publication
(10) Pub. No.: US 2026/0164543 A1
(43) Pub. Date: Jun. 11, 2026

(54) CIRCUIT BOARD AND MANUFACTURING METHOD THEREOF

(71) Applicant: SAMSUNG ELECTRO-MECHANICS CO., LTD., Suwon-si (KR)

(72) Inventor: Taekyun Bae, Suwon-si (KR)

(73) Assignee: SAMSUNG ELECTRO-MECHANICS CO., LTD., Suwon-si (KR)

(21) Appl. No.: 19/228,579

(22) Filed: Jun. 4, 2025

(30) Foreign Application Priority Data
Dec. 6, 2024 (KR) 10-2024-0180244

(51) Int. Cl. H05K 1/02; H05K 1/03; H05K 3/06

(52) U.S. Cl. CPC H05K 1/0296; H05K 1/0366; H05K 3/062

(57) ABSTRACT

A circuit board according to an embodiment includes: an insulating layer; a primer layer that is disposed on the insulating layer and includes a first uneven portion; and a conductive line that is disposed on the first uneven portion of the primer layer. The conductive line includes: a first conductive line including a second uneven portion corresponding to the first uneven portion; and a second conductive line disposed on the first conductive line.

### CROSS-REFERENCE TO RELATED APPLICATION

This application claims priority to and the benefit of Korean Patent Application No. 10-2024-0180244 filed at the Korean Intellectual Property Office on Dec. 6, 2024, the entire contents of which are incorporated herein by reference.

### BACKGROUND

### 1. Technical Field

The present disclosure relates to a circuit board and a manufacturing method thereof.

### 2. Description of the Related Art

A circuit board forms a circuit pattern with a conductive material on an insulating layer, and a higher density and finer circuit pattern is required due to a recent trend of miniaturization and weight reduction of an electronic component.

To form the finer circuit pattern, various processing methods such as a tenting method, a modified semi-additive process (MSAP) method, and a semi-additive process (SAP) method.

The tenting method is a method of removing an unnecessary portion by etching, makes a circuit pattern easy to process, but makes fine processing difficult.

The MSAP method is a method of forming a circuit pattern on a thin seed layer remaining after etching a copper foil and is advantageous in forming a circuit pattern with a certain pitch or greater, but it is difficult to form a fine circuit pattern with a certain pitch or less using the MSAP method.

Because the SAP method forms a circuit pattern only by plating, there is little difference in a line width between upper and lower portions of the circuit pattern so that the SAP method easily implements a fine circuit pattern but has a complex process and requires a special material. In particular, a prepreg constituting a copper clad laminate (CCL) that is a material of a core layer used in the SAP method is not suitable for forming a circuit pattern using the SAP method due to low plating adhesion.

### SUMMARY

Embodiments are intended to provide a circuit board and a manufacturing method thereof capable of improving adhesion of a conductive line to easily implement a fine circuit of the conductive line and improve a manufacturing yield.

However, problems to be solved by the embodiments are not limited to the above-described problem and may be variously extended in a range of technical ideas included in the embodiments.

A circuit board according to an embodiment of the present disclosure includes: an insulating layer; a primer layer that is disposed on the insulating layer and includes a first uneven portion; and a conductive line that is disposed on the first uneven portion of the primer layer. The conductive line includes: a first conductive line including a second uneven portion corresponding to the first uneven portion; and a second conductive line disposed on the first conductive line.

The first conductive line may include a copper foil layer, and the second conductive line may include a seed line and a plating line disposed on the seed line.

A surface roughness of the first uneven portion may be greater than a surface roughness of a portion of the primer layer that does not overlap the first conductive line.

A second thickness that is a thickness of the plating line may be greater than a first thickness that is a thickness of the seed line.

The second uneven portion may be disposed at a boundary surface between the primer layer and the first conductive line.

The first uneven portion may be invaginated from a surface of the primer layer, and the second uneven portion may protrude from a surface of the first conductive line.

A portion of the first uneven portion and the second uneven portion may be interlocked with each other.

The insulating layer may include a composite material that may include a resin and a fiber, and the primer layer may include a polymer.

The polymer may include at least one selected from an epoxy resin, a polyimide resin, a polyamide imide resin, a polyamide resin, a liquid crystal polymer resin, and a cycloolefin resin.

A surface roughness (Ra) of the first uneven portion may be 0.05 to 0.4 μm.

The first conductive line may include copper.

A manufacturing method of a circuit board according to an embodiment includes: preparing an insulating layer, and sequentially stacking, on the insulating layer, a primer layer including a first uneven portion, and a first conductive layer including a second uneven portion corresponding to the first uneven portion; forming a seed layer on the first conductive layer; exposing a first portion of the seed layer on the seed layer and forming a pattern mask that covers a second portion of the seed layer; forming a plating line on the first portion of the seed layer; removing the pattern mask; and forming a conductive line comprising removing the second portion of the seed layer and the first conductive layer below the second portion of the seed layer.

The removing of the second portion of the seed layer and the first conductive layer below the second portion of the seed layer may include reducing a surface roughness of the primer layer below the second portion of the seed layer to be less than a surface roughness of the first uneven portion of the primer layer.

The forming of the seed layer may include a first electroless plating process, and the forming of the plating line may include a second electroplating process.

The forming of the pattern mask may include: forming a dry film resist on the seed layer; and exposing and developing the dry film resist.

The forming of the conductive line may further include: etching the second portion of the seed layer using the plating line as an etching mask to form a seed line so that a second conductive line is completed; and forming a first conductive line by etching a portion of an exposed first conductive layer using the plating line as an etching mask.

According to the embodiments, a first uneven portion of a primer layer and a second uneven portion of a first conductive line that is a seed layer for forming a conductive line may be interlocked with each other, so that adhesion of the conductive line including the first conductive line is improved. Therefore, a fine circuit of the conductive line may be easily implemented, and a manufacturing yield of a circuit board may be improved.

It is obvious that an effect of the embodiments is not limited to the above-described effect and may be variously extended without departing from the spirit and scope of the present disclosure.

### BRIEF DESCRIPTION OF THE DRAWINGS

FIG. 1 is a cross-sectional view of a circuit board according to an embodiment.

FIG. 2 is a schematic flowchart of a manufacturing method of the circuit board according to an embodiment.

FIGS. 3 to 6 are cross-sectional views sequentially illustrating the manufacturing method of the circuit board according to an embodiment.

FIG. 7 is a view for describing a method of measuring adhesion of a conductive line of the circuit board according to an embodiment.

### DETAILED DESCRIPTION

Embodiments of the present disclosure will be described more fully hereinafter with reference to the accompanying drawings so that those skilled in the art could easily implement the embodiments. The present disclosure may be modified in various ways, all without departing from the spirit or scope of the present disclosure.

In order to clearly describe the present disclosure, parts or portions that are irrelevant to the description are omitted, and identical or similar constituent elements throughout the specification are denoted by the same reference numerals.

Further, the accompanying drawings are provided only in order to allow embodiments disclosed in the present specification to be easily understood and should not be interpreted as limiting the spirit disclosed in the present specification, and it should be understood that the present disclosure includes all modifications, equivalents, and substitutions without departing from the scope and spirit of the present disclosure.

In the drawings, each element's size and thickness are arbitrarily illustrated for ease of description, but the present disclosure is not necessarily limited to those illustrated in the drawings. In the drawings, the thicknesses of some layers and areas are exaggerated for clarity. In the drawings, for ease of description, the thicknesses of some layers and areas are exaggerated.

It should be understood that when an element such as a layer, a film, a region, or a plate is referred to as being “on” or “above” another element, it may be directly on the other element, or an intervening element may also be present. In contrast, when an element is referred to as being “directly on” another element, there is no intervening element present. Further, in the specification, the word “on” or “above” means disposed on or below a referenced part, and does not necessarily mean disposed on the upper side of the referenced part based on a gravitational direction.

Unless explicitly stated to the contrary, the word “comprise” and variations such as “comprises” and “comprising” should be understood to imply the inclusion of stated elements but not the exclusion of any other elements.

Throughout the specification, the phrase “in a plan view” or “on a plane” may mean when an object portion is viewed from above, and the phrase “in a cross-sectional view” or “on a cross-section” may mean when a cross-section taken by vertically cutting an object portion is viewed from the side.

Furthermore, throughout the specification, “connected” does not only mean when two or more elements are directly connected, but also when two or more elements are indirectly connected through other elements, and when they are physically connected or electrically connected, and further, it may be referred to by different names depending on a position or function, and may also be referred to as a case in which respective parts that are substantially integrated are linked to each other.

Hereinafter, various embodiments and variations will be described in detail with reference to the drawings.

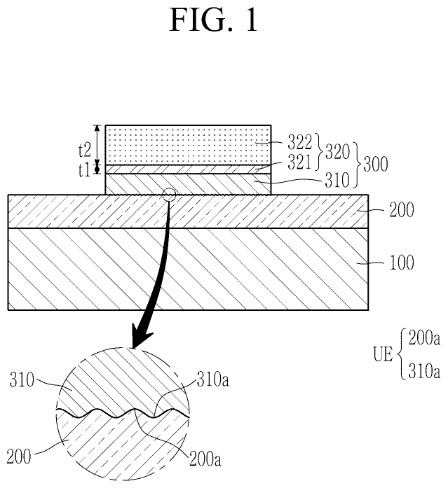

FIG. 1 is a cross-sectional view of a circuit board according to an embodiment.

As shown in FIG. 1, the circuit board according to the embodiment may include an insulating layer 100, a primer layer 200, and a conductive line 300.

The insulating layer 100 may include a composite material of a resin and a fiber. For example, the insulating layer 100 may include a prepreg, an Ajinomoto buildup film (ABF), a photo imageable dielectric (PID), and the like.

The primer layer 200 may be disposed on the insulating layer 100, and may improve adhesion between the insulating layer 100 and the conductive line 300. The primer layer 200 may have a first uneven portion 200a on a surface facing a first conductive line 310. The first uneven portion 200a may be invaginated (or recessed) from a surface of the primer layer 200. A surface roughness (Ra) of the first uneven portion 200a may be 0.05 to 0.4 μm. In this case, the surface roughness of the first uneven portion 200a may be higher than a surface roughness of a portion of the primer layer 200 that does not overlap the first conductive line 310. That is, in the present embodiment, the first uneven portion 200a is shown as being formed only below the first conductive line 310, but the first uneven portion 200a may be finely formed with a lower surface roughness than the surface roughness of the first uneven portion 200a even in the portion of the primer layer 200 that does not overlap the first conductive line 310. Surface roughness may be measured by a profilometer or a laser scanner. Other methods and/or tools appreciated by one of ordinary skill in the art, even if not described in the present disclosure, may also be used.

The primer layer 200 may include a polymer. For example, the primer layer 200 may include at least one of an epoxy resin, a polyimide (PI) resin, a polyamide imide (PAI) resin, a polyamide (PA) resin, a liquid crystal polymer (LCP) resin, and a cycloolefin (COP) resin.

The conductive line 300 may be disposed on the first uneven portion 200a of the primer layer 200. The conductive line 300 may be applied to a peripheral bump, a signal line, and the like of a circuit board requiring a high level of adhesion.

The conductive line 300 may include the first conductive line 310 and a second conductive line 320 that are stacked.

The first conductive line 310 may include a conductive material such as copper (Cu), aluminum (AI), silver (Ag), tin (Sn), gold (Au), nickel (Ni), lead (Pb), titanium (Ti), or an alloy thereof. The first conductive line 310 may be a copper (Cu) foil.

The first conductive line 310 may have a second uneven portion 310a corresponding to the first uneven portion 200a on a surface thereof. The second uneven portion 310a may be disposed at a boundary surface between the primer layer 200 and the first conductive line 310.

The second uneven portion 310a may protrude from a surface of the first conductive line 310 to be inserted into the first uneven portion 200a of the primer layer 200. That is, the first uneven portion 200a and the second uneven portion 310a may be interlocked with each other. The first uneven portion 200a and the second uneven portion 310a may together form an uneven portion UE.

Because the first uneven portion 200a of the primer layer 200 and the second uneven portion 310a of the first conductive line 310 are interlocked and in contact with each other, adhesion of the conductive line 300 including the first conductive line 310 may be improved. Therefore, a fine circuit of the conductive line 300 may be easily implemented, and a manufacturing yield of the circuit board may be improved.

The second conductive line 320 may have the same pattern as that of the first conductive line 310, and may be disposed on the first conductive line 310. That is, the second conductive line 320 and the first conductive line 310 may overlap each other on a plane, and boundary lines of both ends of the second conductive line 320 and boundary lines of both ends of the first conductive line 310 may coincide with each other.

The second conductive line 320 may include a seed line 321 and a plating line 322.

The seed line 321 may act as a seed layer for forming a plating line through a plating process. The seed line 321 may include a conductive material such as copper (Cu), aluminum (AI), silver (Ag), tin (Sn), gold (Au), nickel (Ni), lead (Pb), titanium (Ti), or an alloy thereof.

The plating line 322 may be a plating layer that is plated using the seed line 321 as a seed layer. In this case, because the plating line 322 is a plating layer and the seed line 321 is a seed layer, a second thickness t2 that is a thickness of the plating line 322 may be greater than a first thickness t1 that is a thickness of the seed line 321. The thicknesses, t1 and t2, may be measured by a scanning electron microscope. Other methods and/or tools appreciated by one of ordinary skill in the art, even if not described in the present disclosure, may also be used.

The plating line 322 may include a conductive material such as copper (Cu), aluminum (AI), silver (Ag), tin (Sn), gold (Au), nickel (Ni), lead (Pb), titanium (Ti), or an alloy thereof.

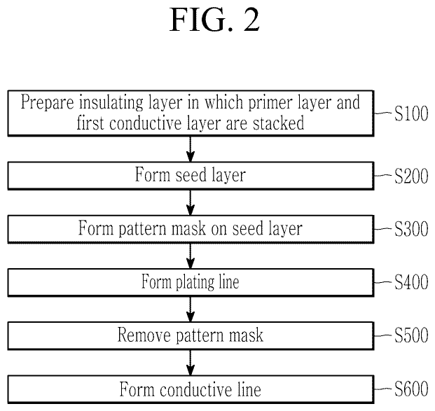

Then, a manufacturing method of the circuit board according to an embodiment will be described in detail with reference to FIGS. 2 to 6 together with FIG. 1.

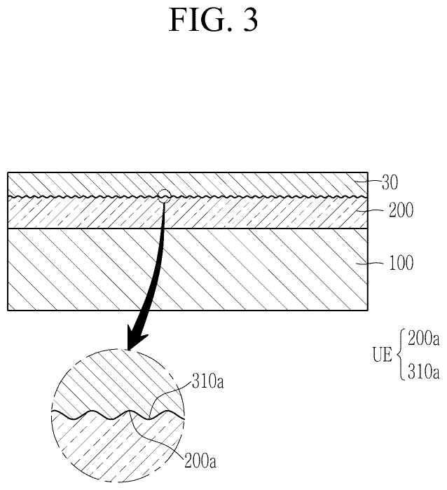

FIG. 2 is a schematic flowchart of the manufacturing method of the circuit board according to an embodiment, and FIGS. 3 to 6 are cross-sectional views sequentially illustrating the manufacturing method of the circuit board according to an embodiment.

As shown in FIG. 2 and FIG. 3, the insulating layer 100 on which the primer layer 200 and a first conductive layer 30 are sequentially stacked on the insulating layer 100 may be prepared (S100).

In this case, the primer layer 200 may be formed on the insulating layer 100, and the first conductive layer 30 may be formed by applying a pressure to the primer layer 200, or the first conductive layer 30 may be formed by attaching the pressurized primer layer 200 on the insulating layer 100.

Because the first conductive layer 30 has the second uneven portion 310a, a shape of the second uneven portion 310a may be transferred to a surface of the primer layer 200 in contact with the second uneven portion 310a by applying a pressure to the first conductive layer 30 to form the first uneven portion 200a on a surface of the primer layer 200. The first conductive layer 30 may include a conductive material such as copper (Cu), aluminum (AI), silver (Ag), tin (Sn), gold (Au), nickel (Ni), lead (Pb), titanium (Ti), or an alloy thereof. The first conductive layer 30 may be a copper (Cu) foil. The first uneven portion 200a and the second uneven portion 310a may together form the uneven portion UE.

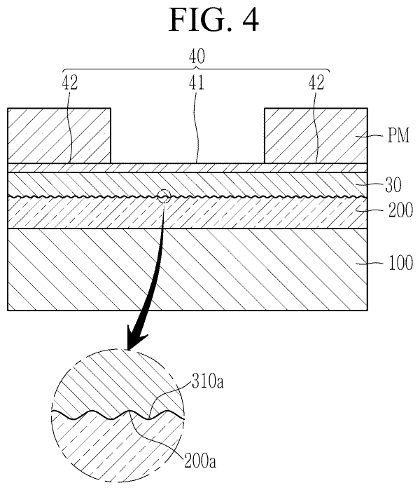

Next, as shown in FIG. 2 and FIG. 4, a seed layer 40 may be formed on the first conductive layer 30 by an electroless plating process (S200). The seed layer 40 may include a conductive material such as copper (Cu), aluminum (Al), silver (Ag), tin (Sn), gold (Au), nickel (Ni), lead (Pb), titanium (Ti), or an alloy thereof.

Next, a pattern mask PM exposing a first portion 41 of the seed layer 40 may be formed (S300). In this case, the pattern mask PM may cover a second portion 42 that is the remaining portion of the first portion 41 of the seed layer 40.

The pattern mask PM may be formed by forming a dry film resist (DFR) on the first conductive layer 30 and exposing and developing the dry film resist.

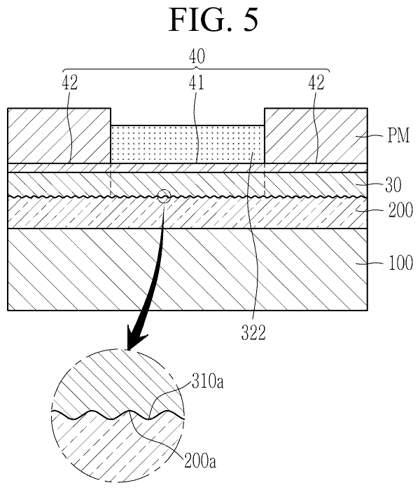

Next, as shown in FIG. 2 and FIG. 5, the plating line 322 may be formed on the first portion 41 of the exposed seed layer 40 by an electroplating process (S400).

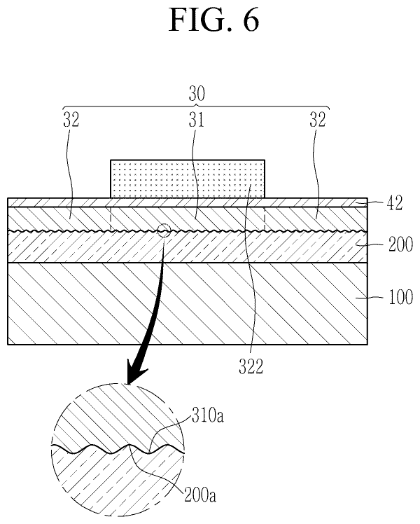

Next, as shown in FIG. 2 and FIG. 6, the pattern mask PM may be removed (S500). Therefore, the second portion 42 of the seed layer 40 disposed below the pattern mask PM may be exposed to the outside.

Next, as shown in FIG. 1 and FIG. 2, the second portion 42 of the seed layer 40 and a second portion 32 of FIG. 6 that is a portion of the first conductive layer 30 below the second portion 42 may be simultaneously etched using the plating line 322 as an etching mask to form the conductive line 300 (S600).

Specifically, because the second portion 42 of the seed layer 40 is etched using the plating line 322 as the etching mask, the first portion 41 of the seed layer 40 may remain with the same pattern as that of the plating line 322 to form the seed line 321 so that the second conductive line 320 including the seed line 321 and the plating line 322 is formed. Because the second portion 32 that is a portion of the first conductive layer 30 exposed using the plating line 322 as an etching mask is successively etched, a first portion 31 of FIG. 6 that is a portion other than the portion of the first conductive layer 30 may remain with the same pattern as that of the second conductive line 320 to form the first conductive line 310. Therefore, the conductive line 300 including the second conductive line 320 and the first conductive line 310 may be formed.

In this case, while the second portion 32 of the first conductive layer 30 is etched, a surface roughness may be reduced by etching a surface of the primer layer 200 disposed below the second portion 32 of the first conductive layer 30. Therefore, a surface roughness of the first uneven portion 200a may be higher than a surface roughness of a portion of the primer layer 200 that does not overlap the first conductive line 310.

Because the conductive line 300 is formed using an MSAP method, a line width of the conductive line 300 may be minimized, and because the first uneven portion 200a of the primer layer 200 and the second uneven portion 310a of the first conductive line 310 are interlocked with each other, a contact area between the primer layer 200 and the first conductive line 310 may be increased so that adhesion of the conductive line 300 including the first conductive line 310 is improved. Therefore, a fine circuit of the conductive line 300 may be easily implemented, and a manufacturing yield of the circuit board may be improved.

Because the conductive line 300 is formed by the MSAP method using the primer layer 200, the adhesion of the conductive line 300 may be improved compared with a conventional SAP method or a conventional MSAP method.

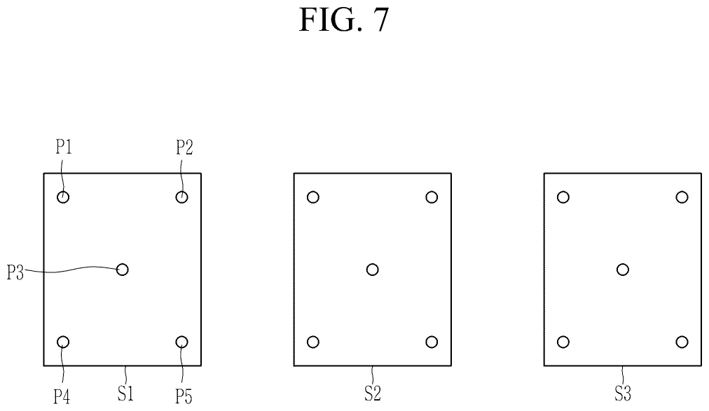

FIG. 7 is a view for describing a method of measuring adhesion of a conductive line of the circuit board according to an embodiment.

As shown in FIG. 7, a first sample S1 may be manufactured by a conventional SAP method, a second sample S2 may be manufactured by a conventional MSAP method, and a third sample S3 may be manufactured by an MSAP method using the primer layer 200 of the present embodiment.

Specifically, the conventional SAP method may form the first sample S1 having a conductive line by the following method. That is, a primer layer may be formed on a sample insulating layer, and a seed layer may be formed on the primer layer by electroless plating. Then, a pattern mask may be formed on a seed layer, and a plating layer may be formed on the seed layer exposed by the pattern mask by electroplating. Then, the pattern mask may be removed, and the seed layer exposed by the removed pattern mask may be removed to form the conductive line.

Additionally, the conventional MSAP method may form the second sample S2 having a conductive line by the following method. That is, a copper foil layer may be formed on a sample insulating layer, and a seed layer may be formed on the copper foil layer by electroless plating. Then, a pattern mask may be formed on the seed layer, and a plating layer may be formed on the seed layer exposed by the pattern mask by electroplating. Then, the pattern mask may be removed, and the seed layer and the copper foil layer exposed by the removed pattern mask may be together removed by an etching process to form the conductive line.

Additionally, adhesion of the conductive line 300 may be measured at a plurality of positions (e.g., a first position P1, a second position P2, a third position P3, a fourth position P4, and a fifth position P5) of each of the first sample S1, the second sample S2, and the third sample S3.

In this case, the adhesion may be measured by a method of separating the conductive line 300 from the insulating layer 100 for the first sample S1, the second sample S2, and the third sample S3.

Table 1 below shows the adhesion of the conductive line 300 measured at the first position P1, the second position P2, the third position P3, the fourth position P4, and the fifth position P5 for each of the first sample S1, the second sample S2, and the third sample S3.

TABLE 1

| | Adhesion of first | Adhesion of second | Adhesion of third |
|---|---|---|---|
| | sample (kgf/cm²) | sample (kgf/cm²) | sample (kgf/cm²) |
| First | 0.63 | 0.72 | 1.15 |
| position | | | |
| Second | 0.64 | 0.70 | 1.10 |
| position | | | |
| Third | 0.65 | 0.74 | 1.20 |
| position | | | |
| Fourth | 0.63 | 0.67 | 1.25 |
| position | | | |
| Fifth | 0.62 | 0.78 | 1.30 |
| position | | | |
| Average | 0.63 | 0.72 | 1.20 |
| value | | | |

As shown in Table 1, the average value of the adhesion of the first sample S1 manufactured by the conventional SAP method may be 0.63 kgf/cm² and the average value of the adhesion of the second sample S2 manufactured by the conventional MSAP method may be 0.72 kgf/cm², but the average value of the adhesion of the third sample S3 manufactured by the present embodiment may be 1.2 kgf/cm². Therefore, it may be seen that the adhesion of the present embodiment is improved by 60% or more compared with the conventional MSAP method.

While this disclosure has been described in connection with what is presently considered to be practical embodiments, it should be understood that the disclosure is not limited to the disclosed embodiments, but, on the contrary, is intended to cover various modifications and equivalent arrangements included within the spirit and scope of the appended claims.

What is claimed is:

1. A circuit board comprising:
an insulating layer;
a primer layer that is disposed on the insulating layer and includes a first uneven portion; and
a conductive line that is disposed on the first uneven portion of the primer layer,
wherein the conductive line comprises:
a first conductive line including a second uneven portion corresponding to the first uneven portion; and
a second conductive line disposed on the first conductive line.

2. The circuit board of claim 1, wherein the first conductive line includes a copper foil layer, and the second conductive line includes a seed line and a plating line disposed on the seed line.

3. The circuit board of claim 2, wherein a surface roughness of the first uneven portion is greater than a surface roughness of a portion of the primer layer that does not overlap the first conductive line.

4. The circuit board of claim 2, wherein a second thickness that is a thickness of the plating line is greater than a first thickness that is a thickness of the seed line.

5. The circuit board of claim 2, wherein the second uneven portion is disposed at a boundary surface between the primer layer and the first conductive line.

6. The circuit board of claim 5, wherein the first uneven portion is invaginated from a surface of the primer layer, and the second uneven portion protrudes from a surface of the first conductive line.

7. The circuit board of claim 6, wherein a portion of the first uneven portion and the second uneven portion are interlocked with each other.

8. The circuit board of claim 1, wherein the insulating layer includes a composite material that includes a resin and a fiber, and the primer layer includes a polymer.

9. The circuit board of claim 8, wherein the polymer includes at least one selected from an epoxy resin, a polyimide resin, a polyamide imide resin, a polyamide resin, a liquid crystal polymer resin, and a cycloolefin resin.

10. The circuit board of claim 1, wherein a surface roughness (Ra) of the first uneven portion is 0.05 to 0.4 μm.

11. The circuit board of claim 1, wherein the first conductive line includes copper.

12. A manufacturing method of a circuit board, comprising:
preparing an insulating layer, and sequentially stacking, on the insulating layer, a primer layer including a first uneven portion, and a first conductive layer including a second uneven portion corresponding to the first uneven portion;
forming a seed layer on the first conductive layer;
exposing a first portion of the seed layer on the seed layer and forming a pattern mask that covers a second portion of the seed layer;
forming a plating line on the first portion of the seed layer;
removing the pattern mask; and
forming a conductive line comprising removing the second portion of the seed layer and the first conductive layer below the second portion of the seed layer.

13. The manufacturing method of claim 12, wherein the removing of the second portion of the seed layer and the first conductive layer below the second portion of the seed layer includes reducing a surface roughness of the primer layer below the second portion of the seed layer to be less than a surface roughness of the first uneven portion of the primer layer.

14. The manufacturing method of claim 12, wherein the forming of the seed layer comprises a first electroless plating process, and the forming of the plating line comprises a second electroplating process.

15. The manufacturing method of claim 12, wherein the forming of the pattern mask comprises:
forming a dry film resist on the seed layer; and
exposing and developing the dry film resist.

16. The manufacturing method of claim 12, wherein the forming of the conductive line further comprises:
etching the second portion of the seed layer utilizing the plating line as an etching mask to form a seed line so that a second conductive line is completed; and
forming a first conductive line by etching a portion of an exposed first conductive layer utilizing the plating line as an etching mask.
